(19) United States
(12) Patent Application Publication
(10) Pub. No.: US 2025/0316408 A1
(43) Pub. Date: Oct. 9, 2025

(54) FLEXIBLE HTS CURRENT LEADS

(71) Applicant: Tokamak Energy Ltd, Abingdon Oxfordshire (GB)

(72) Inventors: Bas van Nugteren, Abingdon Oxfordshire (GB); Greg Brittles, Abingdon Oxfordshire (GB)

(21) Appl. No.: 18/893,688

(22) Filed: Oct. 4, 2024

Related U.S. Application Data
(63) Continuation of application No. 17/274,145, filed on Mar. 5, 2021, now Pat. No. 12,131,837.

(30) Foreign Application Priority Data
Sep. 7, 2018 (GB) 1814582.1

(51) Int. Cl. H01B 12/06; H01R 4/68; H10N 60/20

(52) U.S. Cl. CPC H01B 12/06; H01R 4/68; H10N 60/203

(57) ABSTRACT

According to a first aspect, there is provide an HTS current lead. The HTS current lead comprises an HTS cable comprising a plurality of HTS tapes; a braided sleeve around the HTS cable; and a stabiliser material impregnating the HTS cable and the braided sleeve. The stabiliser material has a melting point above a critical temperature of the HTS tapes and below a thermal degradation temperature of the HTS tapes.

### CROSS-REFERENCE TO RELATED APPLICATIONS

This application claims priority to U.S. patent application Ser. No. 17/274,145 filed on Mar. 5, 2021, which is a national phase application of international application PCT/GB2019/052433 filed Aug. 30, 2019, which claims the benefit of GB1814582.1, filed on Sep. 7, 2018, the entire contents of each are incorporated by reference herein.

### FIELD OF THE INVENTION

The present invention relates to superconductor devices. In particular, the present invention relates to current leads comprising high temperature superconductor.

### BACKGROUND

Superconducting materials are typically divided into “high temperature superconductors” (HTS) and “low temperature superconductors” (LTS). LTS materials, such as Nb and NbTi, are metals or metal alloys whose superconductivity can be described by BCS theory. All low temperature superconductors have a critical temperature (the temperature above which the material cannot be superconducting even in zero magnetic field) below about 30 K. The behaviour of HTS material is not described by BCS theory, and such materials may have critical temperatures above about 30 K (though it should be noted that it is the physical differences in superconducting operation and composition, rather than the critical temperature, which define HTS material). The most commonly used HTS are “cuprate superconductors”—ceramics based on cuprates (compounds containing a copper oxide group), such as BSCCO, or ReBCO (where Re is a rare earth element, commonly Y or Gd). Other HTS materials include iron pnictides (e.g. FeAs and FeSe) and magnesium diborate (MgB₂).

ReBCO is typically manufactured as tapes, with a structure as shown in FIG. 1. Such tape 100 is generally approximately 100 microns thick, and includes a substrate 101 (typically electropolished hastelloy approximately 50 microns thick), on which is deposited by IBAD, magnetron sputtering, or another suitable technique a series of buffer layers known as the buffer stack 102, of approximate thickness 0.2 microns. An epitaxial ReBCO-HTS layer 103 (deposited by MOCVD or another suitable technique) overlays 15 the buffer stack, and is typically 1 micron thick. A 1-2 micron silver layer 104 is deposited on the HTS layer by sputtering or another suitable technique, and a copper stabilizer layer 105 is deposited on the tape by electroplating or another suitable technique, which often completely encapsulates the tape.

The substrate 101 provides a mechanical backbone that can be fed through the manufacturing line and permit growth of subsequent layers. The buffer stack 102 is required to provide a biaxially textured crystalline template upon which to grow the HTS layer, and prevents chemical diffusion of elements from the substrate to the HTS which damage its superconducting properties. The silver layer 104 is required to provide a low resistance interface from the ReBCO to the stabiliser layer, and the stabiliser layer 105 provides an alternative current path in the event that any part of the ReBCO ceases superconducting (enters the “normal” state).

A common issue in the design of superconducting systems such as magnets is to obtain high currents at cryogenic temperatures with minimal heat load to the cryogenic environment. Usually, a high current is generated at room temperature (i.e. outside of the cryogenic environment), and transported into the cryostat by current leads. The current leads are typically a mix of copper (for temperatures around 300 K), brass (for temperatures between 300 K and 77 K), and high temperature superconductors (HTS) (for temperatures below 77 K). Current leads may also be used to transport current in regions of the system at a single temperature.

Other solutions may be used, e.g. having a switched mode power supply which transfers power into the cryostat, but these will generally still involve HTS current leads between the power supply and the superconducting system.

HTS current leads may be either rigid or flexible. Rigid leads may cause mechanical issues due to thermal shrinkage when the cryostat is cooled. Flexible leads must be handled carefully, as HTS tape will develop cracks if it is bent with too small a radius, and will have reduced critical current if it is under strain due to bending while operational.

### SUMMARY

According to a first aspect, there is provide an HTS current lead. The HTS current lead comprises an HTS cable comprising a plurality of HTS tapes; a braided sleeve around the HTS cable; and a stabiliser material impregnating the HTS cable and the braided sleeve. The stabiliser material has a melting point above a critical temperature of the HTS tapes and below a thermal degradation temperature of the HTS tapes.

According to a second aspect, there is provided a method of manufacturing an HTS current lead. An HTS cable is provided, comprising a plurality of HTS tapes. A braided sleeve is placed around the cable. A leak-tight sheath is placed around the braided sleeve. The leak-tight sheath is filled with a stabiliser material, the stabiliser material having a melting point above a critical temperature of the HTS tapes and below a thermal degradation temperature of the HTS tapes. The leak-tight sheath is filled.

According to a third aspect, there is provided a method of reshaping an HTS current lead according to the first aspect and additionally comprising a leak tight sheath around the stabiliser material. The HTS current lead is heated to a temperature above the meting point of the stabiliser material and below the degradation temperature of the HTS tape. The HTS current lead is bent into a desired shape. The HTS current lead is allowed to cool while maintaining it in the desired shape.

### BRIEF DESCRIPTION OF THE DRAWINGS

FIG. 1 is a schematic diagram of an HTS tape;

FIG. 2 is a schematic diagram of an exemplary construction of an HTS current lead;

FIG. 3 is a schematic diagram of an exemplary construction of an HTS current lead comprising terminals.

FIG. 4 is a schematic diagram of an HTS current lead.

FIG. 5A to 5E are schematic diagrams, showing a method of manufacturing an HTS current lead.

FIG. 6A to 6D are schematic diagrams, showing method steps for affixing a first and a second terminal block to an HTS cable.

### DETAILED DESCRIPTION

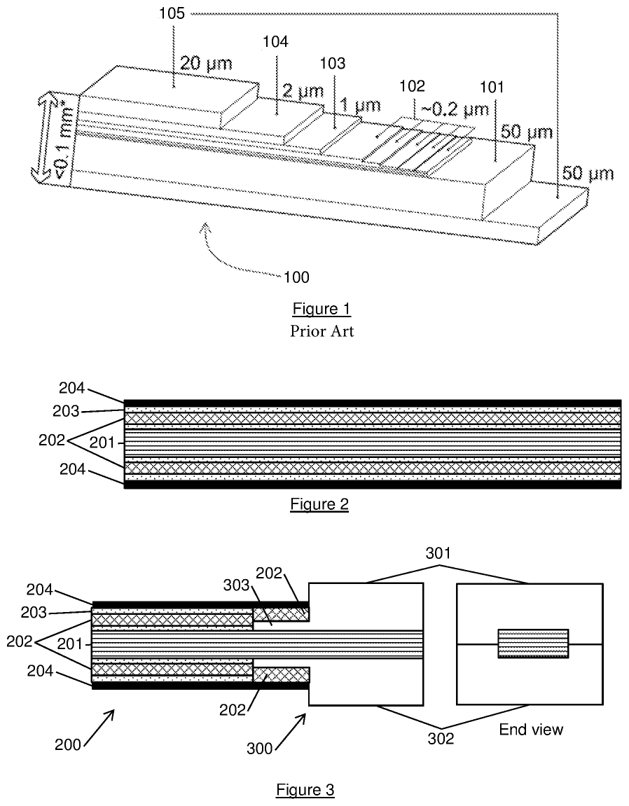

A construction for an HTS current lead is shown in FIG. 2. The HTS current lead comprises a plurality of HTS tapes 201, which are held within a braided sleeve 202. The tapes 201 and braided sleeve 202 are encased in wax 203, which is held in place by a sheath 204.

The HTS tapes may be stacked (i.e. all parallel) or arranged into a cable in some other orientation (e.g. twisted stacks or braided cables).

The braided sleeve acts to make the current lead bulkier, which means that it is much more difficult to bend the current lead with a bending radius which would cause damage to the tapes, as compared to bending the cable alone. The braided sleeve may comprise metal in order to also act as an electrical “stabiliser” for the HTS tapes, i.e. as an alternative current path in the event that the current through the HTS tapes exceeds the critical current. Suitable metals for the braided sleeve include brass or copper, and the metal filaments may be coated with another metal such as PbSn solder.

The braided sleeve may be configured to entirely prevent bending below a certain radius of curvature.

The wax acts to keep the current lead structurally stable during handling of the system and during operation of the superconducting system. The current lead may be heated up to melt the wax, so that it can be bent into a desired shape, and then allowed to cool to retain that shape. Suitable waxes will have a melting point above an intended operating temperature of the current lead (e.g. 77 K, or the critical temperature of the HTS tapes), or above room temperature (290 K, to ensure they are stable at room temperature), but below a degradation temperature of the HTS (i.e. a temperature at which permanent damage to the HTS would occur, usually around 200° C.). If the melting point of the braided sleeve, sheath, or any solder in the HTS current lead is below the HTS degradation temperature, then the melting point of the wax may be below this as well—or heat may be applied in such a way as to prevent the lower melting point components from reaching the same temperature as the wax (e.g. avoiding soldered areas).

While wax is used herein as an example, other substances with a melting point above room temperature and below the HTS degradation temperature would also be suitable for use as stabiliser materials to impregnate the HTS current lead.

The properties of the wax during cryogenic cooling may also be considered—some waxes will break down into powder if cooled to cryogenic temperatures and warmed back to room temperature, and would not be suitable for applications where cycles of cooling and warming are expected (but would be suitable for devices kept at cryogenic temperatures permanently). Which waxes perform well at cryogenic temperatures can be determined by routine experimentation.

The rigidity of the wax at room temperature and at cryogenic temperatures will also be a consideration, depending on the design constraints of the system. More rigid waxes will offer better structural protection during operation (e.g. against Lorentz forces), but may suffer from mechanical issues due to thermal shrinkage. More flexible waxes will offer less protection from Lorentz forces, but will be able to flex more easily to account for thermal shrinkage.

One wax which satisfies the above conditions is beeswax (melting temperature of 60° C., and stable through cryogenic cycles). Where “wax” is used herein, this may also be a mixture of different waxes or other materials to achieve the desired properties.

The sheath 204 may be a heat-shrink material, such that when the wax is heated in order to reshape the cable, the heat shrink material will shrink to encourage the wax to fill any voids in the structure. Once the HTS current lead has been shaped into position and the wax has solidified, the sheath 204 may be removed if desired, or kept on for additional electrical insulation.

Many materials which would be otherwise suitable to provide a leak-tight sheath will become brittle at cryogenic temperatures. Therefore, the sheath 204 may comprise a first “room temperature” sheath, which is leak-tight at room temperature and at the temperature required to melt the wax, and a second “cryogenic” sheath surrounding the “room temperature” sheath, which maintains structural integrity at cryogenic temperatures.

FIG. 3 is a schematic illustration of the connection between an HTS current lead according to FIG. 2, and a terminal block. The terminal block may be used to connect the HTS current lead electrically, thermally, and structurally to other components.

The HTS current lead 200 has the same components as previously—i.e. the HTS tapes 201, braided sleeve 202, wax 203, and sheath 204. The HTS tapes 201 extend beyond the braided sleeve 202 and into the terminal block 300. Additional copper tapes may be placed between the HTS tapes such that they are spaced out further within the terminal block, and provided with additional copper in case of excess current—the terminal block is likely to undergo resistive heating, which will lower the critical current of the tapes and result in a greater risk of quenching, and the excess copper helps mitigate this.

The terminal block may be formed from upper 301 and lower 302 portions, which the HTS tapes are clamped between. Alternatively, the terminal block may be formed as a single unit having a recess or through hole to receive the HTS tapes. Other suitable constructions may also be used. The recess or through hole in the terminal block (or the space between the two portions in the clamped example) may fit the HTS tapes to within 0.1 mm to allow them to be easily soldered to the terminal block.

The braided sleeve 202 surrounds a protrusion 303 on the side of the terminal block, and the sheath 204 also extends around this protrusion. The braided sleeve 202, HTS tapes 201, and terminal block 300 may be connected by soldering, e.g. by dipping the entire block and the protrusions in solder (keeping the sheath 204 and wax 203 away from the hot solder). The solder should be chosen to have a melting point below the degradation temperature of the HTS. Sealant may be applied to be join between the terminal block and the sheath 204.

The HTS current lead, including terminal blocks may be manufactured by the following steps:
1. HTS tapes are cut to length, and assembled into a cable (e.g. by stacking).
2. A first terminal block is placed over one end of the cable.
3. The braided sleeve is cut to the desired length and slid over the cable, up to the first terminal block and around the protrusion.
4. The first terminal block is dipped in solder to fix the HTS cable and braided sleeve to each other and to the first terminal block.
5. The sheath is slid over the braided sleeve, and sealed at the end adjacent to the first terminal block.
6. The sheath is filled with wax, and temporarily fixed at the end furthest from the first terminal block, such that that end is held some way away from where the second terminal block will be attached.
7. The second terminal block is placed over the free cable end, and the braided sleeve is slid over the protrusion of second terminal block.
8. The second terminal block is dipped in solder to fix the HTS cable and braided sleeve to each other and the second terminal block.
9. The sheath is slid down to second terminal block, and sealed at that end.
10. The assembly is heated to melt the wax (and shrink the heat-shrink material, if that is used for the sheath).

These steps may be varied appropriately for terminals other than the terminal blocks described with reference to FIG. 3. In general, forming the HTS current lead will require the steps of:
1. Providing an HTS cable comprising a plurality of tapes.
2. Placing a braided sleeve around the cable.
3. Placing a sheath around the braided sleeve.
4. Filling the sheath with wax (either molten or in the form of pellets).
5. Sealing the sheath.
6. Melting the wax if pellets were used.
   These steps may be re-ordered or broken up into sub-steps as required to connect the HTS cable to the terminals used.

Where HTS cables comprising stacked tapes are used (and potentially for other cable designs), the relative orientations of the terminal blocks will be limited to close to their orientation when the cable is made (e.g. if the terminal blocks are parallel, then they will remain close to parallel as the HTS current lead is bent). This is because significantly changing the relative orientations of the terminal blocks would require HTS tapes on one side of the stack to extend relative to HTS tapes on the other side of the stack. This can be mitigated by pre-bending the stacked HTS cable prior to affixing the second terminal block, so that the terminal blocks are in the desired relative orientation.

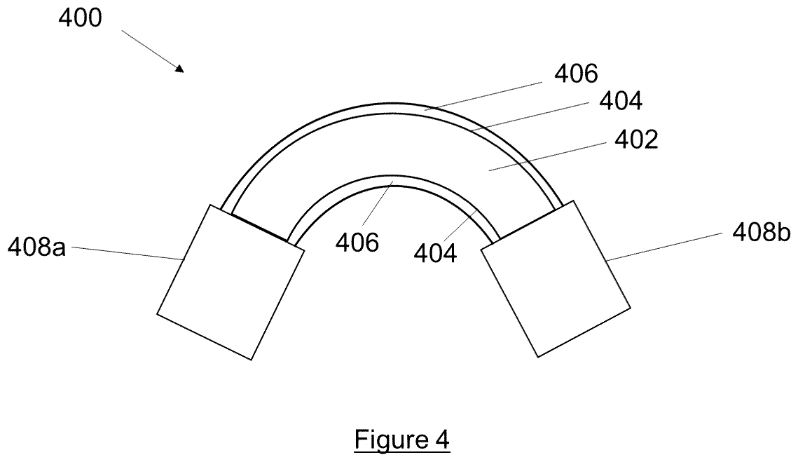

FIG. 4 is a schematic diagram of an HTS current lead 400. The HTS current lead comprises an HTS cable 402 including a plurality of HTS tapes and a braided sleeve 404 around the HTS cable. A stabiliser material 406, with a melting point above 290 K but below a thermal degradation temperature of the HTS tapes, impregnates the HTS cable and the braided sleeve. The HTS cable is bent and the terminal blocks 408a, 408b at each end of the HTS cable are at an angle to each other. Each terminal block is electrically connected to the HTS tape and configured for electrical connection to external components (not shown).

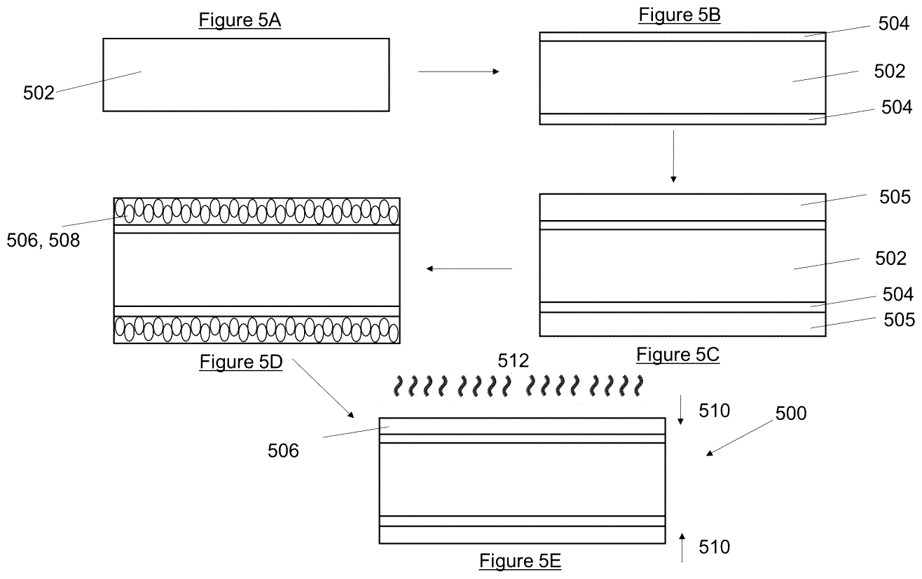

FIG. 5A to 5E are schematic diagrams, showing a method of manufacturing an HTS current lead 500. In FIG. 5A, an HTS cable 502, including a plurality of HTS tapes, is provided. In FIG. 5B, a braided sleeve 504 is placed around the cable. In FIG. 5C, a leak-tight sheath 505 is placed around the braided sleeve. In FIG. 5D, the leak-tight sheath is filled with a stabiliser material 506, having a melting point above 290 K and below a thermal degradation temperature of the HTS tapes. As shown, this may include inserting pellets 508 of the stabiliser material into the leak-tight sheath. The pellets may then be melted. The method also includes sealing the leak-tight sheath. The leak-tight sheath may be formed from a heat shrink material. As shown in FIG. 5E, the leak-tight sheath may be heated 510, following the step of filling the leak-right sheath with stabiliser material, to melt the stabiliser material and to shrink (denoted by arrows 512) the sheath.

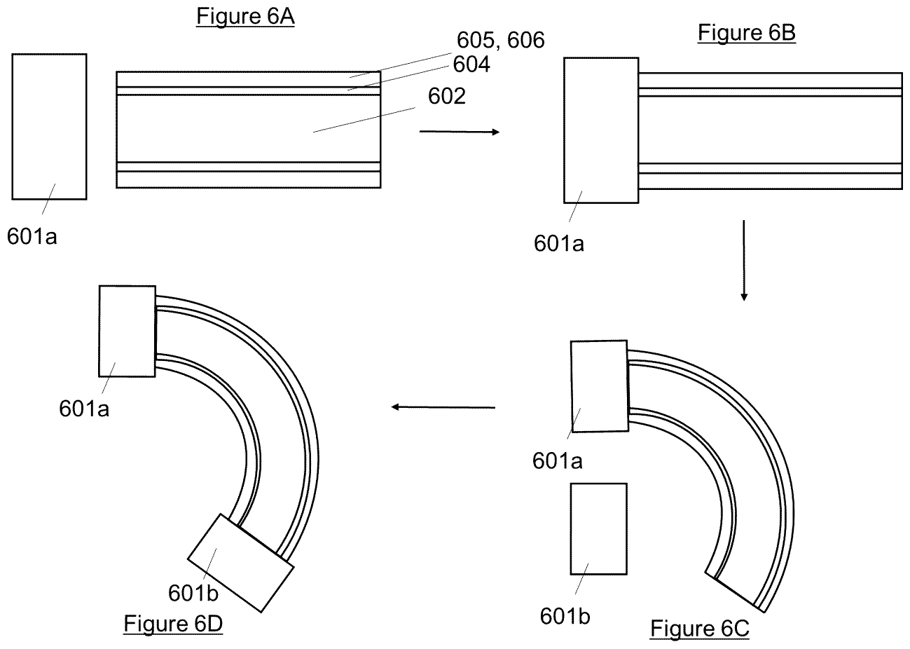

FIG. 6A to 6D are schematic diagrams, showing method steps for affixing a first and a second terminal block 601a, 601b to an HTS cable. In FIG. 6A, an HTS cable 602, including a plurality of HTS tapes, is provided. A braided sleeve 604 is placed around the cable, and a leak-tight sheath 605 is placed around the braided sleeve. A stabiliser material 606, having a melting point above 290 K but below a thermal degradation temperature of the HTS tapes, fills the leak-tight sheath. The leak-tight sheath is sealed. In FIG. 6B, the first terminal block 601a is affixed to the HTS cable at one end. In FIG. 6C, the HTS cable is bent. In FIG. 6D, the second terminal 601b block is affixed to the HTS cable at the other end, while the HTS cable is bent, such that the first and second terminal blocks are at an angle relative to one another.

1. A reshapeable high temperature superconducting, HTS, current lead comprising:
an HTS cable comprising a plurality of HTS tapes;
a braided sleeve around the HTS cable; and
a stabiliser material impregnating the HTS cable and the braided sleeve, the stabiliser material having a melting point above 290 K and below a thermal degradation temperature of the HTS tapes.

2. An HTS current lead according to claim 1, wherein the HTS current lead is rigid when the stabiliser material is solid and wherein the HTS current lead is reshapeable when the stabiliser material is at a temperature above the melting point of the stabiliser material.

3. An HTS current lead according to claim 1, wherein the HTS current lead is reshapeable from a first shape to a second shape when the stabiliser material is at a temperature above the melting point of the stabiliser material; and wherein the HTS current lead is configured to retain said second shape of the HTS current lead when the stabiliser material is cooled from the temperature above the melting point of the stabiliser material to a temperature below the melting point of the stabiliser material.

4. An HTS current lead according to claim 1, wherein the HTS cable comprises a stack of parallel HTS tapes.

5. An HTS current lead according to claim 1, further comprising:
a terminal block at each end of the HTS cable, each terminal block being electrically connected to the HTS tape, and being configured for electrical connection to external components.

6. An HTS current lead according to claim 1, wherein the stabiliser material is a wax.

7. An HTS current lead according to claim 1, wherein the braided sleeve comprises a metal, and is electrically connected to the HTS cable.

8. An HTS current lead according to claim 7, wherein the metal is copper or brass.

9. An HTS current lead according to claim 5, wherein the terminal block at each end of the HTS cable is soldered to the HTS cable.

10. An HTS current lead according to claim 5, wherein the terminal block at each end of the HTS cable is affixed to the braided sleeve.

11. An HTS current lead according to claim 5, wherein the terminal block at each end of the HTS table is soldered to the braided sleeve.

12. An HTS current lead according to claim 10, wherein the terminal block at each end of the HTS cable comprises a protrusion extending around a portion of the HTS cable, and the braided sleeve extends around the protrusion.

13. An HTS current lead according to claim 1, and comprising a leak-tight sheath surrounding the stabiliser material.

14. An HTS current lead according to claim 13, wherein the leak-tight sheath is removable.

15. An HTS current lead according to claim 13, wherein the leak-tight sheath comprises an inner sheath formed from a leak-tight material, and an outer sheath formed from a material which maintains structural integrity after cooling to below 77 K.

16. An HTS current lead according to claim 1, wherein the braided sleeve is configured to prevent bending of the HTS cable below a threshold radius of curvature.

17. A method of manufacturing a reshapeable HTS current lead, the method comprising:
providing an HTS cable comprising a plurality of HTS tapes;
placing a braided sleeve around the HTS cable;
placing a sheath around the braided sleeve;
filling the sheath with a stabiliser material, the stabiliser material having a melting point above 290 K and below a thermal degradation temperature of the HTS tapes; and
sealing sheath.

18. A method according to claim 17, wherein the sheath is a leak-tight sheath.

19. A method according to claim 17, and comprising:
affixing the HTS cable to a first terminal block at one end;
affixing the HTS cable to a second block at the other end; and
affixing the braided sleeve to the first or second terminal block.

20. A method according to claim 19, wherein affixing the braided sleeve and the HTS cable to the first or second terminal block comprises dipping the first or second terminal block, a portion of the HTS cable, and a portion of the braided sleeve together into a bath of solder.

21. A method of reshaping an HTS current lead, comprising:
providing an HTS cable comprising a plurality of HTS tapes, a braided sleeve around the HTS cable, and a stabiliser material impregnating the HTS cable and the braided sleeve, the stabiliser material having a melting point above a critical temperature of the HTS tape and below a thermal degradation temperature of the HTS tapes;
heating the HTS current lead to a temperature above the melting point of the stabiliser material and below the degradation temperature of the HTS tape;
bending the HTS current lead into a desired shape; and
allowing the HTS current lead to cool while maintaining it in the desired shape.

22. A method of reshaping an HTS current lead according to claim 21, wherein the HTS cable comprises a sheath encapsulating the stabiliser material.
